(19) United States
(12) Patent Application Publication
(10) Pub. No.: US 2024/0234239 A1
(43) Pub. Date: Jul. 11, 2024

(54) COOLED POWER MODULE

(71) Applicant: GM GLOBAL TECHNOLOGY OPERATIONS LLC, DETROIT, MI (US)

(72) Inventors: Muhammad Hussain Alvi, Troy, MI (US); Junghoon Kim, ANN ARBOR, MI (US); Yilun Luo, Ann Arbor, MI (US); Kevin David Corpetti-Vazquez, Davisburg, MI (US)

(21) Appl. No.: 18/150,406

(22) Filed: Jan. 5, 2023

(51) Int. Cl. H01L 23/373; H01L 21/48; H01L 23/00; H01L 23/473; H01L 23/498; H01L 25/065; H01L 25/07

(52) U.S. Cl. CPC H01L 23/3735; H01L 21/4882; H01L 23/473; H01L 23/49833; H01L 23/49844; H01L 24/32; H01L 24/48; H01L 25/0655; H01L 25/072; H01L 2224/32225; H01L 2224/48225; H01L 2924/10161; H01L 2924/1203; H01L 2924/13055; H01L 2924/13091; H01L 2924/1432; H01L 2924/1433

(57) ABSTRACT

Aspects of the disclosure include a 1.5 sided cooled power module for enhanced cooling and gate connections. An exemplary cooled power module can include an upside direct bond copper (DBC) having a first top copper layer, a first bottom copper layer, and a first dielectric layer between the first top copper layer and the first bottom copper layer. A downside DBC includes a second top copper layer, a second bottom copper layer, and a second dielectric layer between the second top copper layer and the second bottom copper layer. One or more dies are positioned between the upside DBC and the downside DBC. The upside DBC is sized such that a portion of an uppermost surface of the one or more dies remains exposed. Bond wires are placed on the exposed portion of the one or more dies and terminated on the first top copper layer of the upside DBC.

### INTRODUCTION

The subject disclosure relates to power electronics modules, and particularly to a 1.5 sided cooled power module for enhanced cooling and gate connections.

High-density power electronics modules are used in a variety of applications, ranging from power delivery and electronics support in electric vehicles (EVs) and hybrid electric vehicles (HEVs) to control and power systems in industrial, marine, aerospace, locomotive, and utility applications. The ongoing development of high-density power electronics modules has placed increasingly large strains on the thermal management systems tasked with cooling these powered semiconductor devices. Modern silicon-based power electronics devices, for example, are capable of dissipating up to 500 W/cm². Natural and forced air cooling systems can only handle heat fluxes up to a few W/cm², while liquid cooling plates can achieve heat fluxes on the order of twenty to a hundred W/cm².

Cooled power modules can manage heat fluxes that exceed 1000 W/cm² and are increasingly relied upon for this function. The planar cooled power module package typically includes one or more upper power switch dies and one or more lower power switch dies sandwiched between two direct bond copper (DBC) substrates (the so-called double-sided cooled power module). Simpler, single-sided cooled power modules include a single DBC, but otherwise function similarly. In many configurations, cold plates (often with pin fins on one side) are directly bonded to an outside surface of the DBC substrate(s).

### SUMMARY

In one exemplary embodiment a 1.5 sided cooled power module for enhanced cooling and gate connections can include an upside direct bond copper (DBC) having a first top copper layer, a first bottom copper layer, and a first dielectric layer between the first top copper layer and the first bottom copper layer. A downside DBC includes a second top copper layer, a second bottom copper layer, and a second dielectric layer between the second top copper layer and the second bottom copper layer. One or more dies are positioned between the upside DBC and the downside DBC. The downside DBC is sized to completely cover a bottommost surface of the one or more dies and the upside DBC is sized such that a portion of an uppermost surface of the one or more dies remains exposed. One or more bond wires are placed on the exposed portion of the one or more dies, the one or more bond wires terminate on the first top copper layer of the upside DBC.

In some embodiments, the one or more bond wires provide gate and source connections from the one or more dies to the first top copper layer. In some embodiments, gate and kelvin source traces are etched on outer boundaries of the first top copper layer of the upside DBC and isolated from a majority of the first top copper layer used for cooling.

In addition to one or more of the features described herein, in some embodiments, the first bottom copper layer is sized to a width less than a width of the second top copper layer.

In some embodiments, the one or more dies each include one of a central processing unit, a graphics processing unit, an application-specific integrated circuit, a metal-oxide-semiconductor field-effect transistor (MOSFET), a field-effect transistor (FET), a bipolar junction transistor (BJT), an Insulated Gate Bipolar Transistor (IGBT), and a diode.

In some embodiments, the first dielectric layer and the second dielectric layer each include at least one of a ceramic material, silicon nitride (SiN), aluminum-oxide (Al₂O₃), and aluminum-nitride (AlN).

In some embodiments, the first top copper layer and the first bottom copper layer are directly bonded to respective surfaces of the first dielectric layer. In some embodiments, the second top copper layer and the second bottom copper layer are directly bonded to respective surfaces of the second dielectric layer.

In some embodiments, the one or more bond wires replace trace etching on the first top copper layer.

In another exemplary embodiment a vehicle includes an electric motor and a cooled power module coupled to the electric motor. The cooled power module can include an upside DBC having a first top copper layer, a first bottom copper layer, and a first dielectric layer between the first top copper layer and the first bottom copper layer. A downside DBC includes a second top copper layer, a second bottom copper layer, and a second dielectric layer between the second top copper layer and the second bottom copper layer. One or more dies are positioned between the upside DBC and the downside DBC. The downside DBC is sized to completely cover a bottommost surface of the one or more dies and the upside DBC is sized such that a portion of an uppermost surface of the one or more dies remains exposed. One or more bond wires are placed on the exposed portion of the one or more dies, the one or more bond wires terminate on the first top copper layer of the upside DBC.

In yet another exemplary embodiment a method for providing a 1.5 sided cooled power module for enhanced cooling and gate connections can include forming an upside DBC having a first top copper layer, a first bottom copper layer, and a first dielectric layer between the first top copper layer and the first bottom copper layer. The method includes forming a downside DBC having a second top copper layer, a second bottom copper layer, and a second dielectric layer between the second top copper layer and the second bottom copper layer. One or more dies are positioned between the upside DBC and the downside DBC. The downside DBC is sized to completely cover a bottommost surface of the one or more dies and the upside DBC is sized such that a portion of an uppermost surface of the one or more dies remains exposed. One or more bond wires are placed on the exposed portion of the one or more dies, the one or more bond wires terminate on the first top copper layer of the upside DBC.

The above features and advantages, and other features and advantages of the disclosure are readily apparent from the following detailed description when taken in connection with the accompanying drawings.

### BRIEF DESCRIPTION OF THE DRAWINGS

Other features, advantages and details appear, by way of example only, in the following detailed description, the detailed description referring to the drawings in which:

FIG. 1 is a vehicle configured in accordance with one or more embodiments;

FIG. 2 is a cross-sectional view of a 1.5 sided cooled power module in accordance with one or more embodiments;

FIG. 3 is a top-down view of a downside direct bond copper (DBC) in accordance with one or more embodiments;

FIG. 4A is a top-down view of the top copper layer of the upside DBC in accordance with one or more embodiments;

FIG. 4B is a top-down view of the bottom copper layer of the upside DBC in accordance with one or more embodiments;

FIG. 5 is a top-down view of an upside DBC in accordance with one or more embodiments;

FIG. 6A is a first cross-sectional view “X” of an alternative embodiment of the 1.5 sided cooled power module in accordance with one or more embodiments;

FIG. 6B is a second cross-sectional view “Y” of an alternative embodiment of the 1.5 sided cooled power module in accordance with one or more embodiments;

FIG. 7A is a first top-down view of the alternative embodiment of the 1.5 sided cooled power module shown in FIG. 6A in accordance with one or more embodiments;

FIG. 7B is a second top-down view of the alternative embodiment of the 1.5 sided cooled power module shown in FIG. 6A in accordance with one or more embodiments;

FIG. 8A is a cross-sectional view of yet another alternative embodiment of the 1.5 sided cooled power module in accordance with one or more embodiments;

FIG. 8B is a detailed view of an example embodiment of the clips of the 1.5 sided cooled power module shown in the detail view of FIG. 8A in accordance with one or more embodiments;

FIG. 8C is a detailed view of another example embodiment of the clips of the 1.5 sided cooled power module shown in the detail view of FIG. 8A in accordance with one or more embodiments;

FIG. 9 is a computer system according to one or more embodiments; and

FIG. 10 is a flowchart in accordance with one or more embodiments.

### DETAILED DESCRIPTION

The following description is merely exemplary in nature and is not intended to limit the present disclosure, its application or uses. It should be understood that throughout the drawings, corresponding reference numerals indicate like or corresponding parts and features. As used herein, the term module refers to processing circuitry that may include an application specific integrated circuit (ASIC), an electronic circuit, a processor (shared, dedicated, or group) and memory that executes one or more software or firmware programs, a combinational logic circuit, and/or other suitable components that provide the described functionality.

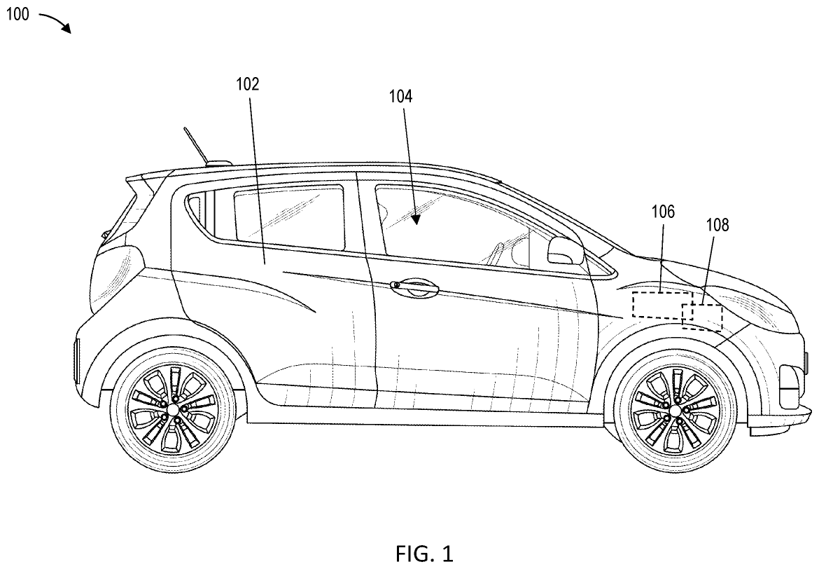

A vehicle, in accordance with an exemplary embodiment, is indicated generally at 100 in FIG. 1. Vehicle 100 is shown in the form of an automobile having a body 102. Body 102 includes a passenger compartment 104 within which are arranged a steering wheel, front seats, and rear passenger seats (not separately indicated). Within the body 102 are arranged a number of components, including, for example, an electric motor 106 (shown by projection under the front hood). The electric motor 106 is shown for ease of illustration and discussion only. It should be understood that the configuration, location, size, arrangement, etc., of the electric motor 106 is not meant to be particularly limited, and all such configurations (including multi-motor configurations) are within the contemplated scope of this disclosure. As will be detailed herein, the vehicle 100 further includes a 1.5 sided cooled power module 108 (shown by projection near the front of the vehicle 100).

The 1.5 sided cooled power module 108 is shown for ease of illustration and discussion only. It should be understood that the configuration, location, size, arrangement, etc., of the 1.5 sided cooled power module 108 is not meant to be particularly limited, and all such configurations (including configurations having a plurality of cooled power modules) are within the contemplated scope of this disclosure.

As discussed previously, high-density power electronics modules require powerful thermal management systems. Conventional thermal management systems rely on single-sided and double-sided cooled power modules for heat extraction. Single-sided cooled power modules are natively limited to heat extraction on a single side of a module and consequently require more die area for the same cooling as double-sided modules. Double-sided cooled power modules, however, have complicated manufacturing tradeoffs. For example, typical double-sided cooled power modules often compromise on cost and switching performance due to the use of dual substrates and the lack of kelvin source connections.

This disclosure introduces a 1.5 sided cooled power module that offers the manufacturing simplicity of a single-sided module while retaining the cooling benefits of a double-sided module. As used herein, a “1.5 sided” cooled power module refers to a structural feature of cooled power modules described herein having an upside direct bond copper (DBC) with only partial die coverage (where a double-sided module would provide full coverage). In some embodiments, the upside DBC bonds with the die in the active area but leaves the gate and kelvin source exposed, allowing access to the gate source via wire bonding and the top surface of the upside substrate. Notably, the power connections are uninterrupted by gate(s) connections, improving thermal and electromagnetic performance.

Cooled power modules constructed in accordance with one or more embodiments offer several technical advantages over prior thermal management solutions. In particular, 1.5 sided cooled power modules offer a partial double-sided layout with top and bottom active area coverage for cooling. Advantageously, the top and bottom active areas are the primary targets (heat generators) for cooling. The result is a 1.5 sided cooled power module offering a substantially similar cooling profile to that provided by full double-sided modules with a simpler manufacturing and design implementation.

1.5 sided cooled power modules expose the gate pads, providing two-sided heat extraction from an underlying die with a reduced substrate size. The gate and kelvin source connections can be made simply by using bondwires and the top copper surface of the upside DBC. In some embodiments, the 1.5 sided cooled power module is implemented in a planar power layout having continuous DBC coppers without isolation etching. In some embodiments, the upside DBC includes wells and vias to avoid (or mitigate) gate path etching on the bottom copper. 1.5 sided cooled power modules constructed in accordance with one or more embodiments enable thermistor layouts with high symmetry and proximity to the target die.

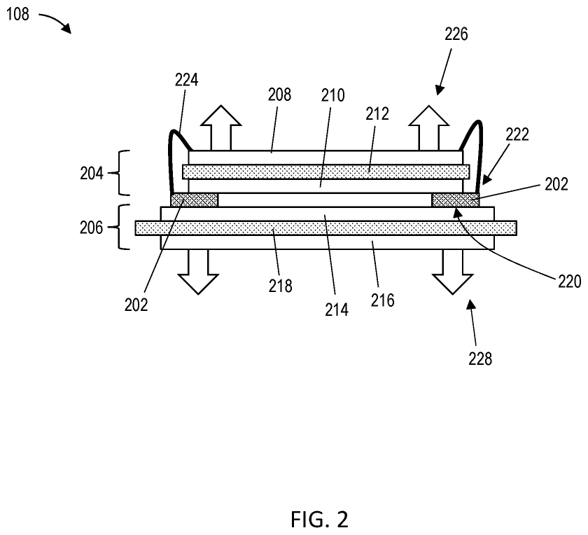

FIG. 2 illustrates a cross-sectional view of a 1.5 sided cooled power module 108 in accordance with one or more embodiments. The 1.5 sided cooled power module 108 can be included within or coupled to an electric motor (e.g., the electric motor 106 of FIG. 1), although other applications are within the contemplated scope of this disclosure.

In some embodiments, the 1.5 sided cooled power module 108 includes one or more dies 202 positioned between an upside DBC 204 and a downside DBC 206. The dies 202 can include any of a variety of integrated circuits, including central processing unit(s), graphics processing unit(s), application-specific integrated circuit(s), Insulated Gate Bipolar Transistors (IGBTs), metal-oxide-semiconductor field-effect transistors (MOSFETs), emitters and collectors, diodes, etc., made out of materials such as silicon (Si), silicon carbide (SiC), gallium nitride (GaN), diamond and other semiconductors. While shown as having two dies 202 for ease of illustration and discussion, the number, type, and configuration of the dies 202 in the 1.5 sided cooled power module 108 is not meant to be particularly limited and all configurations are within the contemplated scope of this disclosure. For example, a typical electrical layout associated with this application is a half bridge for a voltage source inverter.

In some embodiments, the upside DBC 204 includes a first top copper layer 208, a first bottom copper layer 210, and a first dielectric layer 212. The first dielectric layer 212 can include any suitable DBC base material, such as, for example, ceramics, silicon nitride (SiN), aluminum-oxide (Al₂O₃), and/or aluminum-nitride (AlN), although other configurations and materials are possible. In some embodiments, the first top copper layer 208 and the first bottom copper layer 210 are directly bonded to respective surfaces of the first dielectric layer 212.

In some embodiments, the downside DBC 206 includes a second top copper layer 214, a second bottom copper layer 216, and a second dielectric layer 218, although other configurations and materials are possible. The second top copper layer 214 and the second bottom copper layer 216 can be directly bonded to respective surfaces of the second dielectric layer 218 in a similar manner as discussed with respect to the upside DBC 204. The second dielectric layer 218 can include a same or a different base material as the first dielectric layer 212.

While not separately shown, top and bottom surfaces of the dies 202 can include an adhesion layer (also referred to as a wetting layer or as a die attachment layer) to secure attachment between the upside DBC 204 and the downside DBC 206, respectively. The adhesion layers can include, for example, sintered silver.

As shown in FIG. 2, the downside DBC 206 extends to completely cover a bottommost surface 220 of the dies 202. Conversely, the upside DBC 204 is sized such that a portion of an uppermost surface 222 of the dies 202 remains exposed (i.e., a 1.5 sided configuration). In some embodiments, the first bottom copper layer 210 of the upside DBC 204 is made of a width less than a width of the second top copper layer 214 of the downside DBC 206. In this manner, the gate and Kelvin source pad on the top of the dies 202 remain exposed and available for wire bonding connections to the first top copper layer 208.

In some embodiments, the 1.5 sided cooled power module 108 can further include one or more bond wires 224. In some embodiments, the bond wires 224 can be placed to provide gate and source connections from the dies 202 to the first top copper layer 208 of the upside DBC 204. Notably, using bond wires 224 for gate and source connections in this manner obviates the need for gate source trace etching on the first bottom copper layer 210 of the upside DBC 204 (which is otherwise present in conventional double-sided cooled power modules). Instead, the first top copper layer 208 of the upside DBC 204 will include traces at the corners for the gate source.

As further shown in FIG. 2, a top heat path 226 illustrates the removal of heat (Q) from the uppermost surface 222 of the dies 202. Similarly, a bottom heat path 228 illustrates the removal of heat (Q) from the bottommost surface 220 of the dies 202.

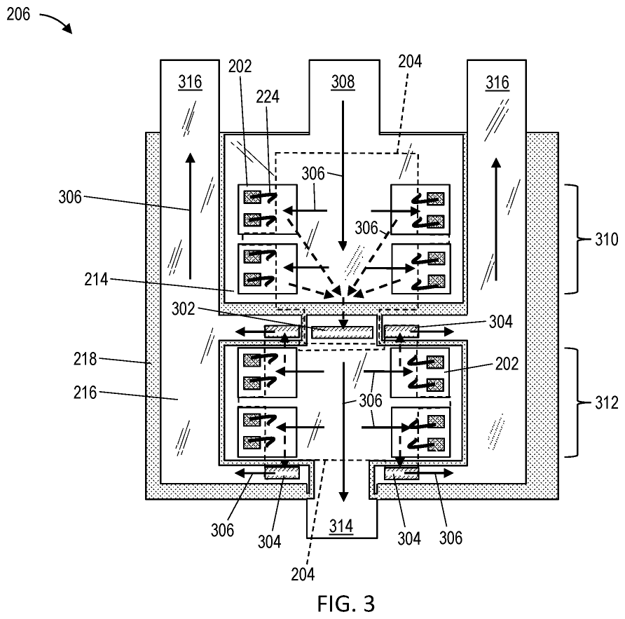

FIG. 3 illustrates a top-down view of the downside DBC 206 of the 1.5 sided cooled power module 108 in accordance with one or more embodiments. The upside DBC 204 is shown via a projection for positional reference. In some embodiments, downside DBC 206 includes a main spacer 302 and one or more additional spacers 304. While shown as having a single main spacer 302 and four additional spacers 304, the number and configuration of the spacers is not meant to be particularly limited and all such configurations are within the contemplated scope of this disclosure. The main spacer 302 and the one or more additional spacers 304 provide electrical continuity across and between the downside DBC 206, the upside DBC 204, and the dies 202 to achieve a desired electrical layout such as a half bridge circuit of an inverter.

As shown in FIG. 3, a current path (also referred to as a commutation loop 306) runs through the downside DBC 206 and the upside DBC 204. Observe that portions of the commutation loop 306 within the upside DBC 204 are shown via projection in a similar manner as the upside DBC 204.

In the commutation loop 306, current enters from a positive direct current (DC+) terminal 308 on the downside DBC 206 and follows the indicated, solid current path arrows to the dies 202. In some embodiments, the dies 202 are arranged into a first portion, referred to as high side dies 310 of a half bridge circuit, and a second portion, referred to as low side dies 312 of the half bridge circuit. In some embodiments, current from the DC+ terminal 308 reaches the high side dies 310 and traverses through the high side dies 310 and into the upside DBC 204.

Configuring the commutation loop 306 with continuous and wide copper and compact and highly coupled DC+, negative direct current (DC−) and alternating current (AC) current paths in this manner allows for high magnetic field cancellation and very low equivalent series inductance in addition to improved thermals and simpler and cost effective manufacturing.

The commutation loop 306 continues through the upside DBC 204 as the current makes its way to the main spacer 302 (roughly in the middle of the downside DBC 206, as indicated by dashed current paths). A first portion of the current traverses the main spacer 302 to re-enter the downside DBC 206. A second portion of the current leaves the downside DBC 206 via an AC terminal 314.

Entering the downside DBC 206 from the main spacer 302, the first portion of the current reaches the low side dies 312 (as indicated by the solid current path) and traverses through the low side dies 312 back into the upside DBC 204. The current then follows the dashed current path towards the one or more additional spacers 304 and re-enters the downside DBC 206 for the last time prior to leaving the downside DBC 206 via DC− terminals 316.

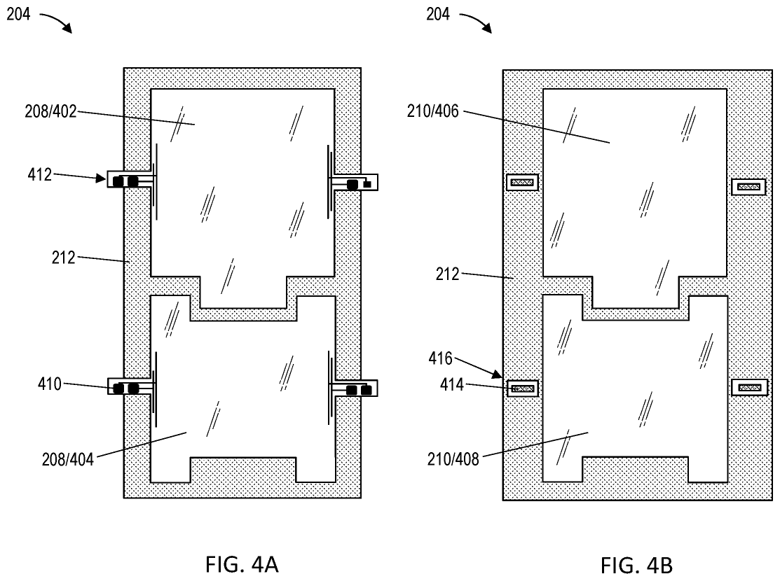

FIG. 4A illustrates a top-down view of the first top copper layer 208 of the upside DBC 204 in accordance with one or more embodiments. FIG. 4B illustrates a top-down view of the first bottom copper layer 210 of the upside DBC 204 in accordance with one or more embodiments. In some embodiments, the first top copper layer 208 of the upside DBC 204 includes a high side copper layer 402 electrically isolated from a low side copper layer 404 via the first dielectric layer 212. Similarly, the first bottom copper layer 210 of the upside DBC 204 can include a high side copper layer 406 electrically isolated from a low side copper layer 408 via the first dielectric layer 212.

In some embodiments, the first top copper layer 208 of the upside DBC 204 includes routing 410. In some embodiments, the routing 410 includes gate and/or kelvin source routing starting from the bond wires 224 coming from the dies 202. In some embodiments, the first top copper layer 208 includes one or more extension regions 412 (also referred to as routing pads or routing islands). The extension regions 412 can extend beyond the perimeter of the first dielectric layer 212 (as shown). In some embodiments, the routing 410 terminates within the one or more extension regions 412 and extends into the remaining (bulk) portions of the first top copper layer 208.

In some embodiments, the first bottom copper layer 210 of the upside DBC 204 includes one or more thermistor(s) 414. In some embodiments, the first bottom copper layer 210 includes one or more conductive islands 416. The conductive islands 416 can be electrically isolated from the first bottom copper layer 210 via the first dielectric layer 212 (as shown). In some embodiments, a thermistor 414 is placed on each of the conductive islands 416. In some embodiments, the thermistor(s) 414 are placed symmetrically in a close proximity to the dies 202 (refer to FIG. 3 and the projection of the upside DBC 204 adjacent to the dies 202).

Constructing the upside DBC 204 in this manner allows the upside DBC 204 to serve three functions simultaneously. First, access to the gate and kelvin source provides stable switching—typically unavailable in double sided cooling modules. Second, symmetric thermistor placement in close proximity to each die improves thermal performance by reducing degradation. Third, the cooling function itself that is typically associated with DBC modules. In some embodiments, approximately 30 percent of the overall cooling is provided by the upside DBC 204 (based upon analytical methods).

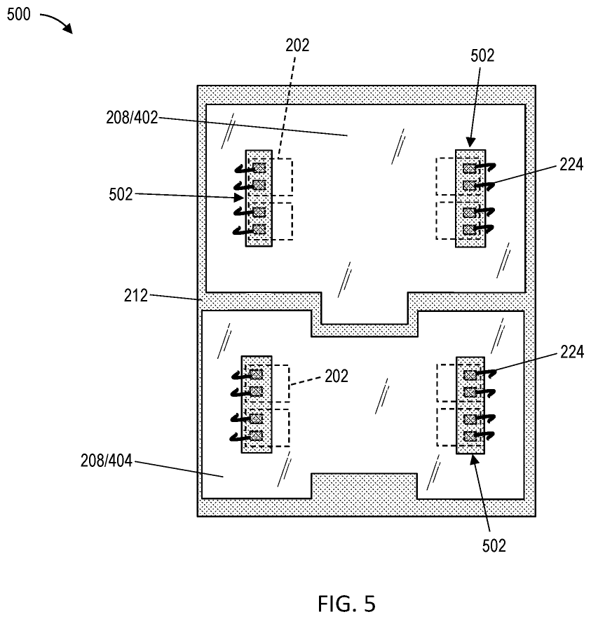

FIG. 5 illustrates a top-down view of an upside DBC 500 in accordance with one or more embodiments. The upside DBC 500 is constructed in a similar manner as the upside DBC 204 described previously, except that the upside DBC 500 includes wells 502. In some embodiments, the wells 502 are positioned to expose respective gate source connections on the dies 202. The dies 202 are shown via a projection for positional reference.

Constructing the upside DBC 500 in this manner allows for conductive portions of the upside DBC 500 (e.g., the high side copper layer 402 and/or the low side copper layer 404) to be extended relative to the upside DBC 204 without losing access to the dies 202. Moreover, expanding the conductive portions allows a substantially double sided cooling effect while retaining kelvin pin access and close-to-die temperature sensors via bond wires, spacers, and/or vias.

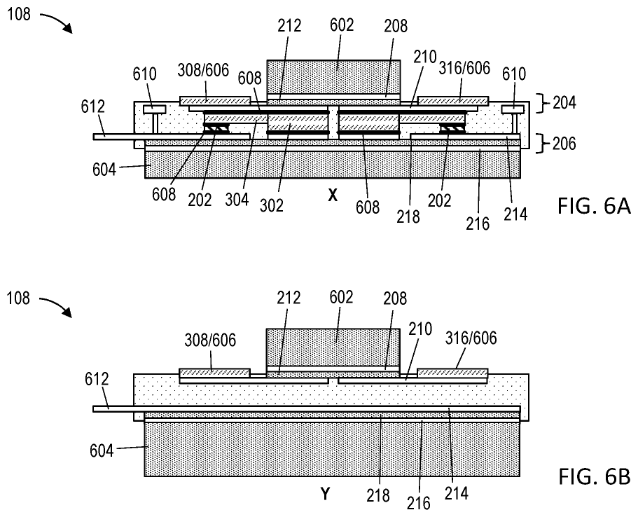

FIG. 6A illustrates a first cross-sectional view “X” of an alternative embodiment of the 1.5 sided cooled power module 108 in accordance with one or more embodiments. FIG. 6B illustrates a second cross-sectional view “Y” of an alternative embodiment of the 1.5 sided cooled power module 108 in accordance with one or more embodiments. The 1.5 sided cooled power module 108 shown in FIGS. 6A and 6B functions in a similar manner as the 1.5 sided cooled power module 108 described previously (refer to FIGS. 2 to 5), except that the embodiment of the 1.5 sided cooled power module 108 shown in FIGS. 6A and 6B includes additional components and functionality.

In some embodiments, the 1.5 sided cooled power module 108 includes a half sided heat transfer path with a top cold plate 602 and a bottom cold plate 604. In some embodiments, the top cold plate 602 is formed on the first top copper layer 208 of the upside DBC 204. In some embodiments, the bottom cold plate 604 is formed on the second bottom copper layer 216 of the downside DBC 206. In some embodiments, the upside DBC 204 and/or the downside DBC 206 is replaced by active metal brazing (AMB) (not separately shown).

In some embodiments, extended spacers 606 are formed on the DC+ terminal 308 and/or the DC− terminal 316. The extended spacers 606 provide a direct, wide connection to the terminals (e.g., the DC+ terminal 308 and/or the DC− terminal 316), lowering inductance (ESL) and improving thermal resistance (Rth).

In some embodiments, the 1.5 sided cooled power module 108 includes one or more sintering layers 608 (also referred to as sintering paste). In some embodiments, one or more pedestals (not separately shown) are formed on the cold plates 602, 604 to improve sintering.

In some embodiments, the 1.5 sided cooled power module 108 includes one or more signal pins 610. The signal pins 610 can include, for example, a gate signal pin, a kelvin source signal pin, and/or a drain signal pin. In some embodiments, the 1.5 sided cooled power module 108 includes an output signal pin 612. In some embodiments, one of more of the signal pins 610 are perpendicular to a voltage flow path from a voltage supply (e.g., VDC) and the output signal pin 612. In some embodiments, the ground signal pin interface and the source signal pin interface are perpendicular to the voltage flow path from the DC+ terminal 308 and/or the DC− terminal 316 to the output signal pin 612.

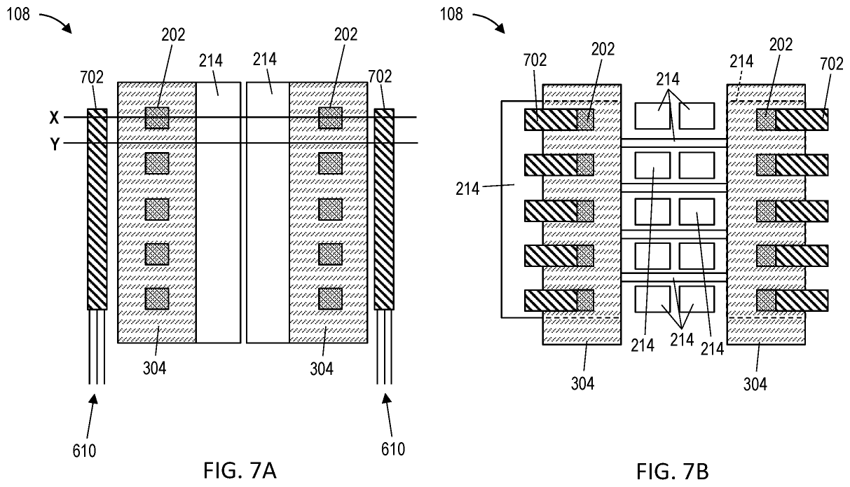

FIG. 7A illustrates a first top-down view of the alternative embodiment of the 1.5 sided cooled power module 108 shown in FIG. 6A in accordance with one or more embodiments. FIG. 7B illustrates a second top-down view of the alternative embodiment of the 1.5 sided cooled power module 108 in accordance with one or more embodiments. In some embodiments, the one or more signal pins 610 (e.g., the gate, source, and drain signal pins) are electrically coupled to the 1.5 sided cooled power module 108 using a signal interface 702.

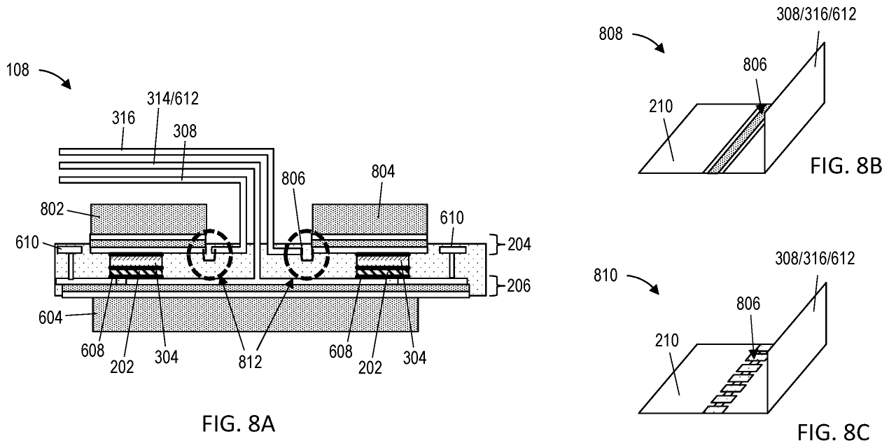

FIG. 8A illustrates a cross-sectional view of yet another alternative embodiment of the 1.5 sided cooled power module 108 in accordance with one or more embodiments. The 1.5 sided cooled power module 108 shown in FIG. 8A functions in a similar manner as the 1.5 sided cooled power module 108 described previously with respect to FIGS. 6A and 6B.

The embodiment of the 1.5 sided cooled power module 108 shown in FIG. 8A retains the signal pins 610 and the signal interface 702 (not separately shown), but splits the top cold plate 602 to define a first top cold plate 802 and a second top cold plate 804. The one or more electrical connections of the DC+ terminal 308, DC− terminal 316, and AC terminal 314 are re-routed between the first top cold plate 802 and the second top cold plate 804. Re-routing DC and AC current paths in this manner cancels out the magnetic fields among positive voltage inputs (V+), outputs (Out), and negative voltage inputs (V−). Moreover, such a configuration allows full double sided cooling at a very low ESL.

In some embodiments, the one or more DC+ terminal 308, DC− terminal 316, AC terminal 314, and the output signal pin 612 are configured as wide busbar terminal coppers that are separated from the upside DBC 204 to improve robustness.

FIGS. 8B and 8C illustrate detailed views of example clip embodiments 808 and 810, respectively, of the clips 806 of the 1.5 sided cooled power module 108 shown in the detail view 812 of FIG. 8A in accordance with one or more embodiments. As shown in FIGS. 8B and 8C, the clips 806 can be configured as a single long structure (FIG. 8B) or as several smaller pieces (FIG. 8C).

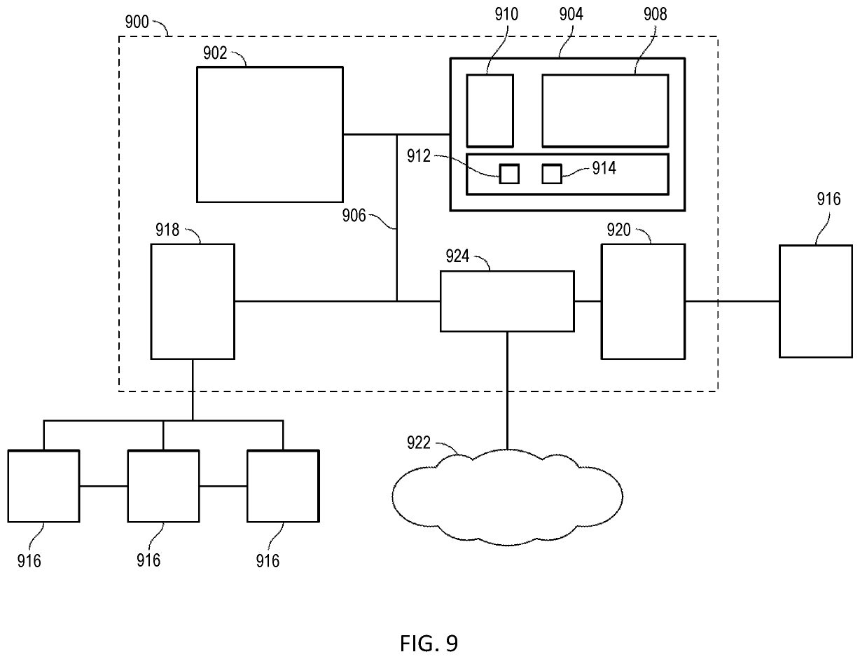

FIG. 9 illustrates aspects of an embodiment of a computer system 900 that can perform various aspects of embodiments described herein. In some embodiments, the computer system 900 can be incorporated within or in combination with a power module (e.g., the 1.5 sided cooled power module 108 of FIG. 2). The computer system 900 includes at least one processing device 902, which generally includes one or more processors for performing a variety of functions. More specifically, the computer system 900 can include the logic necessary to direct a current through a power module (via, e.g., DC+, DC−, and AC terminals of the 1.5 sided cooled power module 108 shown in FIG. 3).

Components of the computer system 900 include the processing device 902 (such as one or more processors or processing units), a system memory 904, and a bus 906 that couples various system components including the system memory 904 to the processing device 902. The system memory 904 may include a variety of computer system readable media. Such media can be any available media that is accessible by the processing device 902, and includes both volatile and non-volatile media, and removable and non-removable media.

For example, the system memory 904 includes a non-volatile memory 908 such as a hard drive, and may also include a volatile memory 910, such as random access memory (RAM) and/or cache memory. The computer system 900 can further include other removable/non-removable, volatile/non-volatile computer system storage media.

The system memory 904 can include at least one program product having a set (e.g., at least one) of program modules that are configured to carry out functions of the embodiments described herein. For example, the system memory 904 stores various program modules that generally carry out the functions and/or methodologies of embodiments described herein. A module or modules 912, 914 may be included to perform functions related to monitoring and/or control of a cooled power module, such as, for example, determining an existing temperature of a die, determining a target temperature of a die, determining a cooling rate required for a die, determining a current required to achieve a targeted cooling rate, etc. The computer system 900 is not so limited, as other modules may be included depending on the desired functionality of the vehicle 100. As used herein, the term “module” refers to processing circuitry that may include an application specific integrated circuit, an electronic circuit, a processor (shared, dedicated, or group) and memory that executes one or more software or firmware programs, a combinational logic circuit, and/or other suitable components that provide the described functionality. For example, the module(s) can be configured via software, hardware, and/or firmware to stop charging and/or otherwise isolate one or more cells of a battery pack of the vehicle 100.

The processing device 902 can also be configured to communicate with one or more external devices 916 such as, for example, a keyboard, a pointing device, and/or any devices (e.g., a network card, a modem, vehicle electronic control units (ECUs), etc.) that enable the processing device 902 to communicate with one or more other computing devices. Communication with various devices can occur via Input/Output (I/O) interfaces 918 and 920.

The processing device 902 may also communicate with one or more networks 922 such as a local area network (LAN), a general wide area network (WAN), a bus network and/or a public network (e.g., the Internet) via a network adapter 924. In some embodiments, the network adapter 924 is or includes an optical network adaptor for communication over an optical network. It should be understood that although not shown, other hardware and/or software components may be used in conjunction with the computer system 900. Examples include, but are not limited to, microcode, device drivers, redundant processing units, external disk drive arrays, RAID systems, and data archival storage systems, etc.

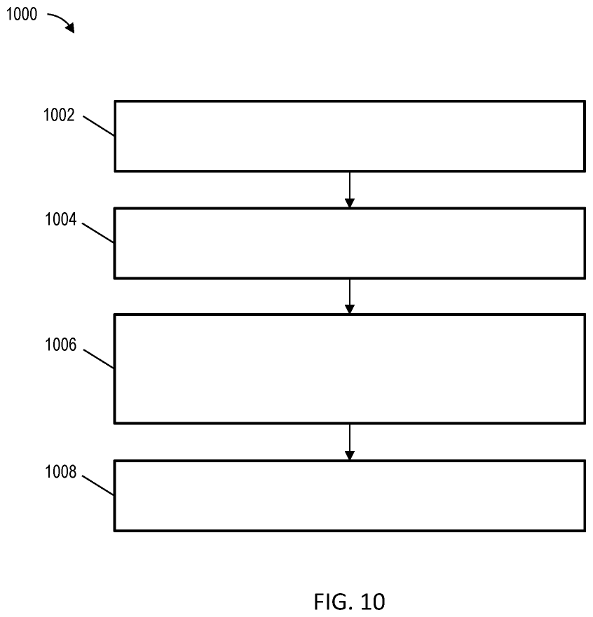

Referring now to FIG. 10, a flowchart 1000 for providing a 1.5 sided cooled power module for enhanced cooling and gate connections is generally shown according to an embodiment. The flowchart 1000 is described in reference to FIGS. 1 to 9 and may include additional steps not depicted in FIG. 10. Although depicted in a particular order, the blocks depicted in FIG. 10 can be rearranged, subdivided, and/or combined.

At block 1002, an upside direct bond copper (DBC) is formed. The upside DBC includes a first top copper layer, a first bottom copper layer, and a first dielectric layer between the first top copper layer and the first bottom copper layer. In some embodiments, the first dielectric layer comprises at least one of a ceramic material, SiN, Al₂O₃, and AlN. In some embodiments, the first top copper layer and the first bottom copper layer are directly bonded to respective surfaces of the first dielectric layer.

At block 1004, a downside DBC is formed. The downside DBC includes a second top copper layer, a second bottom copper layer, and a second dielectric layer between the second top copper layer and the second bottom copper layer. In some embodiments, the second dielectric layer comprises at least one of a ceramic material, SiN, Al₂O₃, and AlN. In some embodiments, the second top copper layer and the second bottom copper layer are directly bonded to respective surfaces of the second dielectric layer.

At block 1006, one or more dies are positioned between the upside DBC and the downside DBC. In some embodiments, the downside DBC is sized to completely cover a bottommost surface of the one or more dies. In some embodiments, the upside DBC is sized such that a portion of an uppermost surface of the one or more dies remains exposed. In some embodiments, the first bottom copper layer has a width less than a width of the second top copper layer. In some embodiments, the one or more dies each include one of a central processing unit, a graphics processing unit, an application-specific integrated circuit, a metal-oxide-semiconductor field-effect transistor (MOSFET), a field-effect transistor (FET), a bipolar junction transistor (BJT), an Insulated Gate Bipolar Transistor (IGBT), and a diode.

At block 1008, one or more bond wires are placed on the exposed portion of the one or more dies. The one or more bond wires terminate on the first top copper layer of the upside DBC. In some embodiments, the one or more bond wires provide gate and source connections from the one or more dies to the first top copper layer. In some embodiments, the one or more bond wires replace trace etching on the first top copper layer. In some embodiments, the one or more bond wires are used for thermistor connections (not separately shown). In some embodiments, gate and kelvin source traces are etched on outer boundaries of the first top copper layer of the upside DBC and isolated from a majority of the first top copper layer used for cooling.

In some embodiments, the upside DBC, downside DBC, and one or more bond wires define a cooled power module. In some embodiments, both sides of the cooled power module are liquid cooled.

The terms “a” and “an” do not denote a limitation of quantity, but rather denote the presence of at least one of the referenced item. The term “or” means “and/or” unless clearly indicated otherwise by context. Reference throughout the specification to “an aspect”, means that a particular element (e.g., feature, structure, step, or characteristic) described in connection with the aspect is included in at least one aspect described herein, and may or may not be present in other aspects. In addition, it is to be understood that the described elements may be combined in any suitable manner in the various aspects.

When an element such as a layer, film, region, or substrate is referred to as being “on” another element, it can be directly on the other element or intervening elements may also be present. In contrast, when an element is referred to as being “directly on” another element, there are no intervening elements present.

Unless specified to the contrary herein, all test standards are the most recent standard in effect as of the filing date of this application, or, if priority is claimed, the filing date of the earliest priority application in which the test standard appears. Unless defined otherwise, technical and scientific terms used herein have the same meaning as is commonly understood by one of skill in the art to which this disclosure belongs.

While the above disclosure has been described with reference to exemplary embodiments, it will be understood by those skilled in the art that various changes may be made and equivalents may be substituted for elements thereof without departing from its scope. In addition, many modifications may be made to adapt a particular situation or material to the teachings of the disclosure without departing from the essential scope thereof. Therefore, it is intended that the present disclosure not be limited to the particular embodiments disclosed, but will include all embodiments falling within the scope thereof.

What is claimed is:

1. A cooled power module comprising:
an upside direct bond copper (DBC) comprising a first top copper layer, a first bottom copper layer, and a first dielectric layer between the first top copper layer and the first bottom copper layer;
a downside DBC comprising a second top copper layer, a second bottom copper layer, and a second dielectric layer between the second top copper layer and the second bottom copper layer;
one or more dies positioned between the upside DBC and the downside DBC, wherein the downside DBC is sized to completely cover a bottommost surface of the one or more dies and the upside DBC is sized such that a portion of an uppermost surface of the one or more dies remains an exposed portion; and
one or more bond wires placed on the exposed portion of the one or more dies, the one or more bond wires terminating on the first top copper layer of the upside DBC.

2. The cooled power module of claim 1, wherein the one or more bond wires provide gate and source connections from the one or more dies to the first top copper layer, and wherein gate and kelvin source traces are etched on outer boundaries of the first top copper layer of the upside DBC and isolated from a majority of the first top copper layer used for cooling.

3. The cooled power module of claim 1, wherein the first bottom copper layer comprises a width less than a width of the second top copper layer.

4. The cooled power module of claim 1, wherein the one or more dies each comprise one of a central processing unit, a graphics processing unit, an application-specific integrated circuit, a metal-oxide-semiconductor field-effect transistor (MOSFET), a field-effect transistor (FET), a bipolar junction transistor (BJT), an Insulated Gate Bipolar Transistor (IGBT), and a diode.

5. The cooled power module of claim 1, wherein both sides of the cooled power module are liquid cooled.

6. The cooled power module of claim 1, wherein the first top copper layer and the first bottom copper layer are directly bonded to respective surfaces of the first dielectric layer, and wherein the second top copper layer and the second bottom copper layer are directly bonded to respective surfaces of the second dielectric layer.

7. The cooled power module of claim 1, wherein the one or more bond wires replace trace etching on the first top copper layer.

8. A vehicle comprising:
an electric motor; and
a cooled power module coupled to the electric motor, the cooled power module comprising:
an upside direct bond copper (DBC) comprising a first top copper layer, a first bottom copper layer, and a first dielectric layer between the first top copper layer and the first bottom copper layer;
a downside DBC comprising a second top copper layer, a second bottom copper layer, and a second dielectric layer between the second top copper layer and the second bottom copper layer;
one or more dies positioned between the upside DBC and the downside DBC, wherein the downside DBC is sized to completely cover a bottommost surface of the one or more dies and the upside DBC is sized such that a portion of an uppermost surface of the one or more dies remains an exposed portion; and
one or more bond wires placed on the exposed portion of the one or more dies, the one or more bond wires terminating on the first top copper layer of the upside DBC.

9. The vehicle of claim 8, wherein the one or more bond wires provide gate and source connections from the one or more dies to the first top copper layer, and wherein gate and kelvin source traces are etched on outer boundaries of the first top copper layer of the upside DBC and isolated from a majority of the first top copper layer used for cooling.

10. The vehicle of claim 8, wherein the first bottom copper layer comprises a width less than a width of the second top copper layer.

11. The vehicle of claim 8, wherein the one or more dies each comprise one of a central processing unit, a graphics processing unit, an application-specific integrated circuit, a metal-oxide-semiconductor field-effect transistor (MOSFET), a field-effect transistor (FET), a bipolar junction transistor (BJT), an Insulated Gate Bipolar Transistor (IGBT), and a diode.

12. The vehicle of claim 8, wherein both sides of the cooled power module are liquid cooled.

13. The vehicle of claim 8, wherein the first top copper layer and the first bottom copper layer are directly bonded to respective surfaces of the first dielectric layer, and wherein the second top copper layer and the second bottom copper layer are directly bonded to respective surfaces of the second dielectric layer.

14. The vehicle of claim 8, wherein the one or more bond wires replace trace etching on the first top copper layer.

15. A method comprising:
forming an upside direct bond copper (DBC) comprising a first top copper layer, a first bottom copper layer, and a first dielectric layer between the first top copper layer and the first bottom copper layer;
forming a downside DBC comprising a second top copper layer, a second bottom copper layer, and a second dielectric layer between the second top copper layer and the second bottom copper layer;
positioning one or more dies between the upside DBC and the downside DBC, wherein the downside DBC is sized to completely cover a bottommost surface of the one or more dies and the upside DBC is sized such that a portion of an uppermost surface of the one or more dies remains an exposed portion; and
placing one or more bond wires on the exposed portion of the one or more dies, the one or more bond wires terminating on the first top copper layer of the upside DBC.

16. The method of claim 15, wherein the one or more bond wires provide gate and source connections from the one or more dies to the first top copper layer, and wherein gate and kelvin source traces are etched on outer boundaries of the first top copper layer of the upside DBC and isolated from a majority of the first top copper layer used for cooling.

17. The method of claim 15, wherein the first bottom copper layer comprises a width less than a width of the second top copper layer.

18. The method of claim 15, wherein the one or more dies each comprise one of a central processing unit, a graphics processing unit, an application-specific integrated circuit, a metal-oxide-semiconductor field-effect transistor (MOSFET), a field-effect transistor (FET), a bipolar junction transistor (BJT), an Insulated Gate Bipolar Transistor (IGBT), and a diode.

19. The method of claim 15, wherein the upside DBC, downside DBC, and one or more bond wires define a cooled power module, and wherein both sides of the cooled power module are liquid cooled.

20. The method of claim 15, wherein the first top copper layer and the first bottom copper layer are directly bonded to respective surfaces of the first dielectric layer, and wherein the second top copper layer and the second bottom copper layer are directly bonded to respective surfaces of the second dielectric layer.
